(19) United States
(12) Patent Application Publication
(10) Pub. No.: US 2009/0138746 A1
(43) Pub. Date: May 28, 2009

(54) Method For Efficient Software Generation Of Multiple Pulse Width Modulated Signals

(76) Inventor: Daniel Richard Klemer, Lexington, KY (US)

Correspondence Address: AUTOLIV ASP INC, 3350 AIRPORT ROAD, OGDEN, UT, 84405, US

(21) Appl. No.: 11/946,312

(22) Filed: Nov. 28, 2007

(51) Int. Cl. G06F 1/08; H03K 3/017

(52) U.S. Cl. 713/502; 327/172

(57) ABSTRACT

Pulse width modulation signals are generated by identifying an event table having a plurality of events, each event including a time to next event parameter. Each desired pulse width modulation signal is characterized by a first event designating a transition from a first state to a second state and a second event designating a transition from the second state back to the first state. An event pointer is set to select a current event and the event table is repeatedly cycled through by updating the output for at least each pulse width modulation signal associated with the current event having a designated state transition, detecting that a time period has lapsed corresponding to the time to next event parameter associated with the current event, incrementing the event pointer to point to a next event in the event table and conveying each pulse width modulation signal to a corresponding circuit.

### BACKGROUND OF THE INVENTION

The present invention relates to pulse width modulation signals and more particularly, to systems, methods and computer program products for generating and using pulse width modulation signals.

In many consumer and industrial electronic products, digital controllers, microprocessors, logic arrays and other digital processing devices, collectively referred to herein as “microcontrollers” are employed to perform a variety of functions. For example, microcontrollers may be utilized to provide data communications, signal processing, interfacing, system control and/or system monitoring. In the performance of such functions, it is frequently necessary for the microcontroller to generate one or more signals that are interfaced with peripheral analog circuits. In this regard, many conventional techniques have been developed to convert digital information from a microcontroller to a corresponding analog signal.

For example, the microcontroller may utilize an integral or otherwise dedicated digital-to-analog (D/A) conversion circuit to derive an analog signal from digital information. Dedicated D/A converters may range from a simple parallel resistor ladder to commercial integrated circuits (ICs) that allow serial or parallel data communication with the microcontroller. Another technique for deriving an analog signal from a microcontroller is to generate a pulse width modulation (PWM) signal by programming the microcontroller to periodically toggle an output pin between on and off states and to electronically filter the resulting pulsed signal to ensure that the AC component of the signal is of negligible amplitude. By varying the relative time in each cycle during which the output is ON, the DC level that is passed through the filter can be made to vary between the digital off and on voltages.

From a hardware perspective, conventional PWM techniques can be utilized to derive an accurate analog signal relatively inexpensively. For example conventional PWM techniques typically require one digital output pin on the microcontroller and minimal external hardware, which may comprise simple passive components for each channel of digital information to be converted to an analog signal. Moreover, many microcontroller designs have evolved dedicated internal circuits for generating PWM signals with minimal involvement of software. However, there may be design situations where either hardware PWM circuits are unavailable, where the number of PWM channels required by a given application exceeds the number of hardware PWM channels available on the microcontroller, or where the frequency response and/or resolution of the desired PWM signals exceeds the capabilities of conventional PWM techniques.

### BRIEF SUMMARY OF THE INVENTION

According to an aspect of the present invention, a method of generating one or more pulse width modulation signals comprises identifying an event table associated with at least one desired pulse width modulation signal. The event table has a plurality of events where each event includes a time to next event parameter. Moreover, each desired pulse width modulation signal is characterized by a first event in the event table that designates a transition from a first state to a second state, e.g., from a low state to a high state, and a second event in the event table that designates a transition from the second state back to the first state, e.g., from the high state to the low state. The method further comprises setting an event pointer to point to a predetermined event in the event table corresponding to a current event and repeatedly cycling through each event in the event table.

The event table is cycled through by updating the output for at least each pulse width modulation signal associated with the current event having a designated state transition, detecting that a time period has lapsed corresponding to the time to next event parameter associated with the current event and incrementing the event pointer to point to a next event in the event table, wherein the event pointer is reset to the first event if the current event is the last event in the event table. The method still further comprises conveying each pulse width modulation signal to a corresponding circuit.

According to a further aspect of the present invention, a pulse width modulation system comprises a microcontroller having a processor, a timer programmable by the processor, at least one output pin and memory accessible by the processor. The system further comprises program code resident in the memory that is executable by the processor to run a pulse width modulation generation algorithm comprising identifying an event table associated with at least one desired pulse width modulation signal. The event table has a plurality of events where each event includes a time to next event parameter. Moreover, each desired pulse width modulation signal is characterized by a first event in the event table that designates a transition from a first state to a second state, e.g., from a low state to a high state, and a second event in the event table that designates a transition from the second state back to the first state, e.g., from the high state to the low state. The program code is further configured for setting an event pointer to point to a predetermined event in the event table, corresponding to a current event and repeatedly cycling through each event in the event table.

The event table is cycled through by updating the output for at least each pulse width modulation signal associated with the current event having a designated state transition, detecting that a time period has lapsed corresponding to the time to next event parameter associated with the current event and incrementing the event pointer to point to a next event in the event table, wherein the event pointer is reset to the first event if the current event is the last event in the event table and conveying each pulse width modulation signal to a corresponding output pin. Moreover, a circuit is coupled to each such output pin.

### BRIEF DESCRIPTION OF THE SEVERAL VIEWS OF THE DRAWINGS

The following detailed description of the preferred embodiments of various embodiments of the present invention can be best understood when read in conjunction with the following drawings, where like structure is indicated with like reference numerals, and in which:

FIG. 1 is a block diagram of an exemplary conversion of a digital signal to a corresponding analog signal, where a first pulse width modulation signal having a first duty cycle is converted into a first analog signal;

FIG. 2 is a block diagram of an exemplary conversion of a digital signal to a corresponding analog signal, where a second pulse width modulation signal having a second duty cycle is converted into a second analog signal;

FIG. 3 is a block diagram of an exemplary system for using pulse width modulation signals according to aspects of the present invention;

FIG. 4 is a flowchart for generating a pulse width modulation signal using events according to aspects of the present invention;

FIG. 5 is a timing diagram of two exemplary pulse width modulation signals illustrating events associated with transitions of the signals;

FIG. 6 is a flowchart for creating an event table by mapping events according to aspects of the present invention;

FIG. 7 is an exemplary blank map that may be used with the method of FIG. 6;

FIG. 8 is an map showing event transitions for a first signal of FIG. 5;

FIG. 9 is an map showing transitions for both signals of FIG. 5;

FIG. 10 is a map showing minimum and maximum keep-out zones;

FIG. 11 is a flow chart of a method of using tables to organize PWM signals;

FIGS. 12A-12I are diagrams illustrating charts used to implement a template look-up for building event tables according to aspects of the present invention;

FIG. 13 is a flow chart illustrating use of regions as guard bands for creating maps according to aspects of the present invention; and

FIG. 14 is a block diagram illustrating keep out regions according to aspects of the present invention.

### DETAILED DESCRIPTION OF THE INVENTION

In the following detailed description of the illustrated embodiments, reference is made to the accompanying drawings that form a part hereof, and in which is shown by way of illustration, and not by way of limitation, specific embodiments in which the invention may be practiced. It is to be understood that other embodiments may be utilized and that changes may be made without departing from the spirit and scope of various embodiments of the present invention.

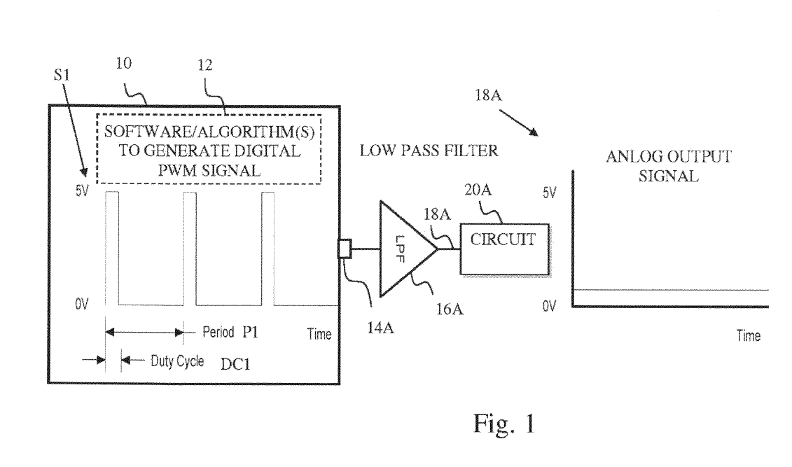

Referring now to the drawings, and particularly to FIG. 1, according to various aspects of the present invention, a microcontroller 10 utilizes a software algorithm 12 to generate one or more pulse width modulation (PWM) signals, which are designated generally by the reference S. In this regard, the software algorithm 12 may be implemented for example, in microcontroller firmware, software code or other instructions executable by the microcontroller 10. The term “microcontroller” is used herein broadly to refer to a digital controller, microprocessor, logic array, field programmable gate array, application-specific integrated circuit or other digital device capable of implementing pulse width modulation as described more fully herein.

The software algorithm 12 generates one or more PWM signals by programmatically controlling the state of a corresponding output pin 14 of the microcontroller 10 for each desired “channel”, i.e., each PWM signal. In particular, each output pin 14 is periodically toggled between high and low states to create a train of digital output pulses. For example, as shown, a first exemplary PWM signal S1 generated by the software algorithm 12 is output to a first output pin 14A of the microcontroller 10. The PWM signal S1 has an output voltage of 5 volts at pin 14A when in an high state and an output voltage of 0 volts when in an low state. Other voltage ranges may alternatively be used to designate high and low states of the output pin 14A and will typically depend upon the supply voltage used to power the particular microcontroller.

Also as shown in the example of FIG. 1, a period P1 is used to define the duration for a single cycle of the PWM signal S1, which is shown as the interval between adjacent rising edges (low to high transitions). Moreover, the duration within a single period P1 that the PWM signal S1 is maintained in the high state relative to the duration of a period P1 defines the duty cycle and is designated DC1. That is, the duty cycle is the ratio of high level signal relative to the period. In practice, the period need not start coincident with the rising edge of the PWM signal S1. Rather, the high and low states of a cycle of the PWM signal S1 may occur anywhere within a period P1.

The PWM signal S1 is coupled from the output pin 14A of the microcontroller 10 to a filter 16A. The filter 16A filters the digital pulse train, e.g., by implementing a low pass filter, to ensure that the AC component of the PWM signal S1 is of negligible amplitude. Moreover, the DC level that is passed through the filter 16A as an analog signal 18A is made to vary between the high state voltage and low state voltage (e.g., 0-5 volts in this example) in a manner that corresponds to the relative duty cycle of the PWM signal S1. An exemplary filter arrangement may comprise a simple, passive resistance/capacitance network. The analog signal 18A output from the filter 16A is coupled as an input to corresponding circuitry 20A to perform a predetermined function. The circuitry 20A may comprise any circuit that utilizes an analog input signal.

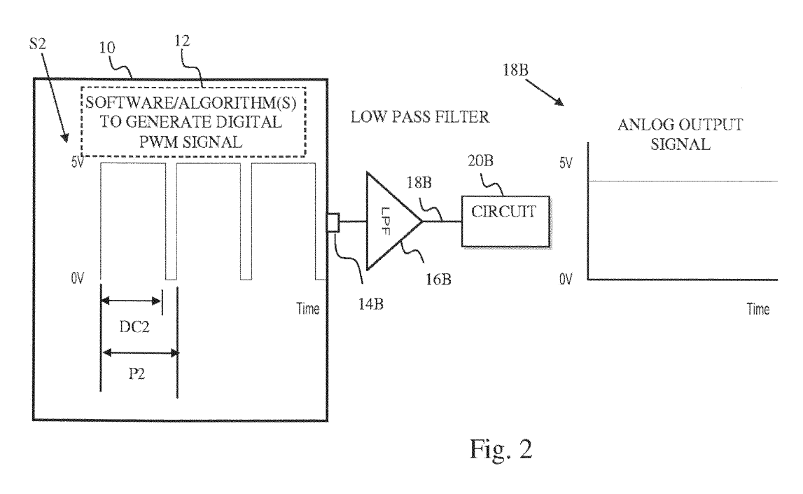

Referring to FIG. 2, for purposes of illustration, the software algorithm 12 of the microcontroller 10 is shown as outputting a second PWM signal, designated S2, on another output pin 14B. The illustrative PWM signal S2 is periodic, having a period of P2 as measured between successive rising edges as shown, and a duty cycle that is designated DC2. The PWM signal S2 is filtered by a second filter 16B, to output a second analog signal 18B which is coupled to circuitry 20B. With reference to FIGS. 1 and 2 generally, assume that DC1<DC2 and P1=P2, then the direct current (DC) value of analog signal 18A< the (DC) value of analog signal 18B. That is, for a given period P, the greater the duty cycle, the greater the corresponding DC analog signal value as schematically represented in the analog output signal graphs to the right of the figures respectively. The filter 16A, 16B may not be necessary, such as where the PWM signal S1, S2 is conveyed directly to a circuit that can process the signal in a digital form, e.g., where the PWM signal is coupled to another processor.

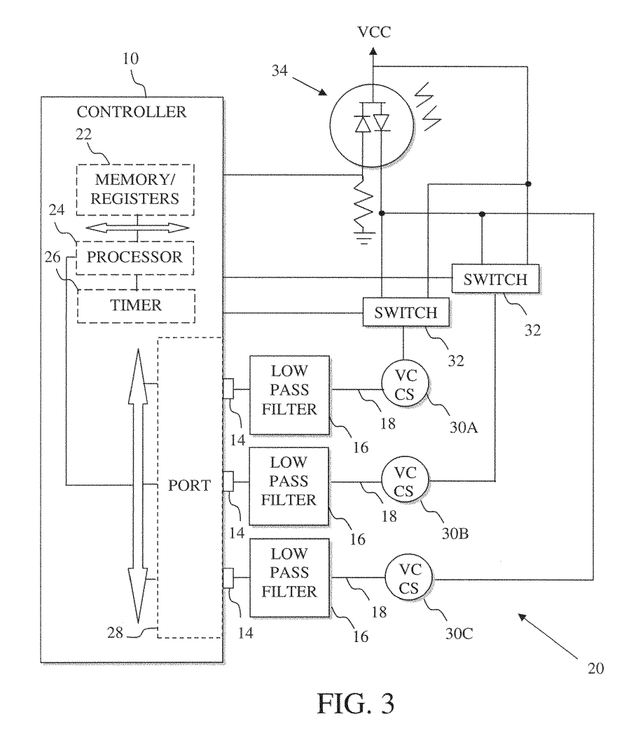

Referring to FIG. 3, to illustrate an example, assume that a microcontroller 10 is part of printhead electronics in a laser printer. As shown, the exemplary microcontroller 10 includes memory and/or registers 22, a processor 24, a timer 26 and a port 28. The port 28 couples each of the illustrated output pins 14 to the processor 24. This simplified block diagram is not intended as being limiting to microcontroller structures, but is utilized to illustrate aspects of the present invention. In the illustrative application, the processor 24 implements the software/algorithm(s) according to various aspects of the present invention. As will be described in greater detail below, the microcontroller includes program code resident in the memory 22 that is executable by the processor 24 to run a pulse width modulation generation algorithm. In general, the pulse width modulation algorithm causes the processor 24 to iteratively update a delay time that is measured by the timer 26 to step through events stored in the memory/registers 22 where the events define edge transitions and/or states of corresponding PWM signals. As the processor 24 steps through the events, the output pins 14 coupled to the port 28 are updated to generate corresponding PWM signals. The program code further dynamically updates the event information based, for example, upon changing the duty cycle of corresponding PWM channels, etc.

Each independently generated PWM signal is filtered by its corresponding low pass filter 16 to derive an analog control signal 18 having a DC voltage that corresponds to its programmed duty cycle. Each analog control signal 18 is further shown as being coupled to circuitry 20. In the illustrative example, the circuitry 20 comprises printhead circuitry for a laser printer. For example, each analog signal 18 may couple to a control voltage input of a corresponding voltage controlled current source 30. First and second current sources 30A, 30B are further coupled via switching logic 32 (also under control of the microcontroller 10) to a laser diode 34 and may define, for example, modulation current sources. A third one of the current sources 30C couples directly to the laser diode 34 and may comprise, for example, a bias current. In this way, the PWM signals output by the microcontroller 10 may be able to control the bias and/or modulation currents of the laser diode 34.

The utilization of PWM techniques, such as described above with reference to FIGS. 1 and 2 allow the microcontroller 10 to output a digital signal that can be converted to an accurate analog signal with a minimum of external hardware. One analog channel is typically associated with a corresponding digital output pin 14 on the microcontroller 10. As such, the microcontroller 10 may utilize as many available port output pins 14 as there are desired analog channels to generate corresponding independently controlled analog signals.

A typical conventional software algorithm for generating a PWM divides a period up into a number of slices, where one slice represents the minimum time resolution for the PWM signal. Correspondingly, the total number of slices within the period represents the available resolution for the digital to analog conversion. The number of high state or “on” slices relative to the total number of slices in a period defines the duty cycle, which corresponds to the DC value of the associated analog signal. Thus, as an example, a 10-bit PWM signal will contain 1024 slices in each period. At 25% duty cycle, the output will remain high in 256 of these slices.

Moreover, many conventional microcontrollers provide at least one timer that may be configured to execute a special interrupt service routine when an event such as a time-out of the timer occurs. As an example, the timer may be set to one slice interval. Each time the slice interval occurs, e.g., as triggered by the timer, a special interrupt routine is called. In the interrupt routine, a slice counter is incremented. If the slice counter is greater than or equal to the period, then the slice count is re-initialized. The slice count is then compared to the duty cycle. If the slice count is greater than or equal to the duty cycle, then an output pin of the microcontroller is set to a low state, e.g., 0V. If the slice count is less than the duty cycle, the output pin of the microcontroller remains or is otherwise toggled to a high state. The timer is reset and control returns back to normal microcontroller processing until the next interrupt.

With the conventional PWM algorithm, the processor is occupied during every PWM slice in order to service the corresponding interrupt service routine. In order to allow the processor to spend a majority of its time performing normal system functions, the timer may be set so that the slice interval is more than twice as long as the time spent in the interrupt service routine. However, this may result in the PWM period being relatively long, corresponding to a relatively slow response. As an example, assume that a microcontroller running at 10 million instructions per second (MIPS) is used to generate a 10-bit PWM signal. If 16 instruction cycles are spent in the interrupt service routine, the timer may be set for example, to generate an interrupt every 32 instruction cycles. Thus:

T_{slice}=32 cycles/(10×10⁶ cycles/sec)=3.2 μsec

T_{period}=1024 slices*3.2 μsec/slice=3.277 msec

F_{PWM}=1/3.277 msec=305 Hz

Under this arrangement, T_{slice} is the slice interval, T_{period} is the PWM period, and F_{PWM} is the PWM frequency. If the filter 16 is designed with a cutoff at 1/10th the PWM frequency, the analog signal response will be only 30.5 Hz. Additionally, the microcontroller will have only 50% of its time available for system functions. Still further, the conventional algorithm is not scalable. For example, if two PWM channels are required, the length of time spent in the interrupt service routine will increase, and therefore the PWM frequency will become even lower. For example, if each additional channel requires an additional 10 instruction cycles in the interrupt service routine, two PWM channels will yield the following performance:

T_{slice2}=52 cycles/(10×106 cycles/sec)=5.2 μsec

T_{period2}=1024 slices*5.2 μsec/slice=5.325 msec

F_{PWM}=1/5.325 msec=188 Hz

If the filter 16 is designed with a cutoff at 1/10th the PWM frequency, the analog signal response is limited to 18.8 Hz for each PWM signal.

Table Driven PWM Generation:

According to aspects of the present invention, let N designate a desired number of PWM signals. Instead of interrupting the microcontroller for each slice of resolution of PWM output, the microcontroller is instead interrupted up to 2N times during each PWM period for N PWM signals. As an example, for N=1, a first interrupt within a PWM period is utilized to toggle or otherwise set the PWM signal to a high state and a second interrupt within the PWM period is utilized to toggle the PWM signal back to a low state. Each edge transition, i.e., the change from low state to high state or the change from high state to low state then corresponds to one event for which the microcontroller toggles the corresponding PWM channel output. Depending upon the specific implementation, the 2N events may be arranged in such a way that the microcontroller is afforded sufficient time to service one event before it is interrupted for the next event, such as may be necessary to ensure that all edge transitions are properly implemented.

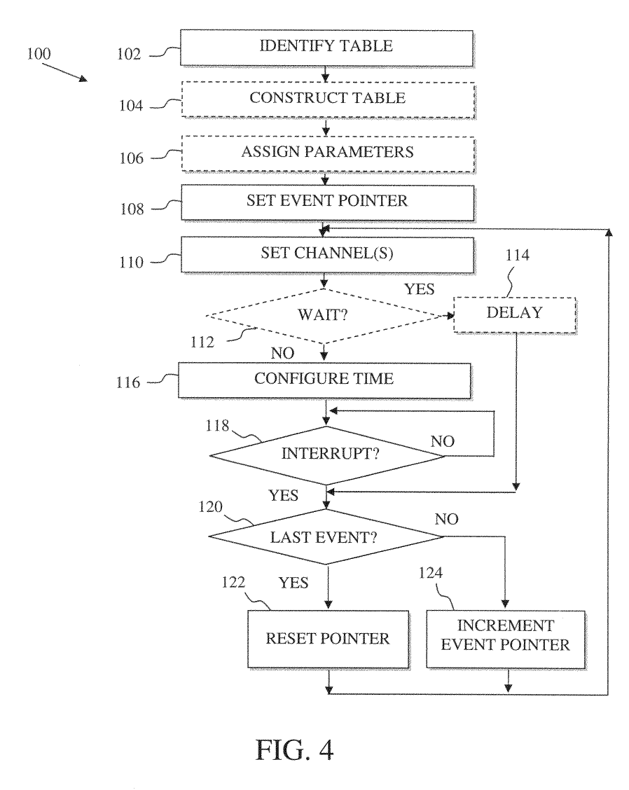

Referring to FIG. 4, a method 100 for generating N PWM channels is illustrated. The method 100 may be implemented, for example, by the microcontroller 10 described with reference to FIGS. 1-3. The method 100 comprises identifying an event table associated with at least one desired PWM signal at 102. As will be described in greater detail herein, the event table has a plurality of events where each event includes a time to next event parameter. Moreover, each desired pulse width modulation signal is characterized by a first event in the event table that designates a transition from a first state to a second state, e.g., from a low state to a high state, and a second event in the event table that designates a transition from the second state back to the first state, e.g., from the high state to the low state.

If an event table is not otherwise available, the method may further be required to construct an event table at 104, which may include up to 2N events for the N desired PWM signals and corresponding PWM channels. As such, at least two events are provided for each desired pulse width modulation channel including a first event corresponding to an edge transition from a low state to a high state and a second event corresponding to an edge transition from a high state to a low state.

Parameters may be assigned at 106 to the events added to the event table constructed at 104. Exemplary parameters may include, the channel(s) affected, a corresponding edge transition direction, i.e., the direction of output change (rising or falling output) for each channel, state information, time to next event and/or other desired information. Not all of the above-describe exemplary parameters are necessarily required. For example, a specific implementation may be able to keep track of which state (high or low) a particular PWM signal is in. Thus, the direction parameter could be eliminated as long as the output was set to the right state initially. Under this exemplary arrangement, the corresponding PWM channel would toggle to the opposite state on subsequent transitions. As another example, the channel and direction may be unnecessary, such as where a data parameter characterizes the state of a multi-bit port. The parameters associated with the event table will be described in greater detail below.

An event pointer is set to point to a predetermined event in the event table at 108, e.g., the first event. Moreover, the microcontroller may map each PWM channel to an associated output pin 14 on the microcontroller chip that has been designated for use as a PWM output. The microcontroller 10 may further set each mapped output pin 14 to a default state, e.g., a high or low value.

To generate the PWM output(s), the microcontroller 10 repeatedly cycles through and processes each event in the event table. As an example, the microcontroller may read the parameter(s) associated with the current event (event identified by the event pointer). Each channel identified by the current event is then set, e.g., toggled or otherwise updated at 110, such as by updating the output for at least each pulse width modulation signal associated with the current event having a designated state transition. Thus, a pulse width modulation output on a corresponding output pin 14 may be toggled or otherwise updated if the corresponding PWM signal is identified by the current event. The state transition or update for an identified PWM signal may be set according to its indicated channel and edge transition direction parameters, its indicated state information such as may be designated by a port data bit, by an instruction to toggle the output state or using other suitable parameter(s) or programming techniques, examples of which will be described in greater detail herein. Optionally, a check may be made at 112 as to whether a short time delay is necessary. If such a check is implemented and a time delay is necessary, a delay is implemented at 114. The optional delay “wait” at 112 and 114 may be implemented, for example, when generating the PWM signals using an interrupt driven service routine where the time to the next event is less than the time necessary to exit and return to the interrupt service routine as will be described in greater detail below, e.g., to account for relatively long or short duty cycles.

Moreover, a timer is configured at 116 to generate an interrupt after a predetermined time interval. For example, the “time to next event” parameter may be read from the current event parameters to determine the duration of time until an interrupt routine should implement the next event.

The method 100 then waits to detect an interrupt at 118. While no interrupt is detected, the corresponding system is free to perform other operations. For example, while the method 100 is waiting for an interrupt, the corresponding microcontroller 10 may be free to perform other system processing functions, e.g., functions not related to the generation of PWM signals. Thus, the microcontroller 10 need not wait in an idle state. If an interrupt is detected at 118 or if an optional delay is implemented at 114, a decision is made at 120 as to whether the current event is the last event in the table. If the current event is the last event in the table, the event pointer is reset to point to the first event in the event table at 122. If the current event is not the last event in the table, the current event pointer is incremented at 124 to point to the next event in the table of events. The flow then loops back to 108 to process the next event in a manner analogous to that described more fully above.

The method 100 illustrates the overall flow for generating N PWM signals. In practice, the method 100 may implemented such that the channel(s) are set at 110, any optional delays are implemented at 112 the timer is configured at 114 and the event pointer is incremented at 120, 122, 124 all within a corresponding interrupt service routine, subroutine or by any other suitable software programming technique.

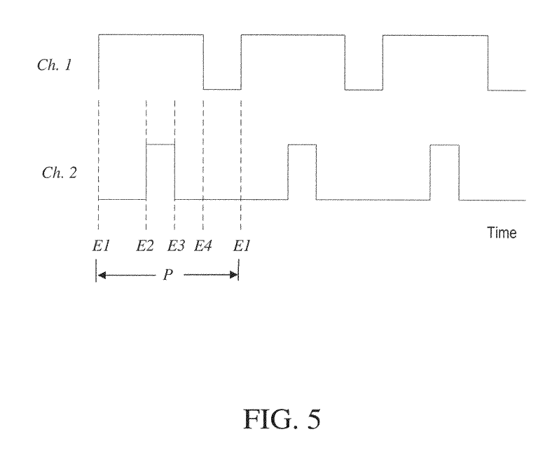

Referring to FIG. 5, an exemplary timing diagram illustrates events (labeled E1-E4) associated with two PWM channels, designated as ‘Ch. 1’ and ‘Ch. 2’ within a PWM cycle having a period P. As there are 2 channels illustrated (N=2), there may be as many as 2N or four events. In this illustrative example, the event E1 corresponds to the rising edge transition for channel 1 (Ch. 1). The event E2 corresponds to the rising edge transition for channel 2 (Ch. 2). The event E3 corresponds to the falling edge transition for channel 2 (Ch. 2) and the event E4 corresponds to the falling edge transition for channel 1 (Ch. 1).

If the method 100 shown in FIG. 4 is implemented for the PWM signals corresponding to Ch. 1 and Ch. 2 shown in FIG. 5, then each interrupt may be precisely timed such that the slice time of the PWM signal is equal to the resolution of the timer generating the interrupt, and for many devices, the timer resolution may be as small as one microcontroller instruction cycle. As an illustrative example, a microcontroller running at 10 MIPS generating the PWM signals corresponding to Ch. 1 and Ch. 2 of FIG. 5 at 10-bit resolution using the method 100 of FIG. 4 would exhibit a performance of:

T_{slice}=1 cycle/(10×10⁶ cycles/sec)=100 nsec

T_{period}=1024 slices*100 nsec/slice=102.4 μsec

F_{PWM}=1/102.4 μsec=9766 Hz

If a corresponding filter 16 is designed with a cutoff at 1/10th the PWM frequency, the analog signal response is limited to 976 Hz (compared to 18.8 Hz in the example of a conventional algorithm). Also, even if the time spent in the interrupt service routine is 26 cycles (16+10), as in the previous example, the same microcontroller spends:

T_{service}=4 events*26 cycles/event=104 cycles

T_{percent}=104 cycles/1024 cycles*100%=10.2%

As such, instead of the microcontroller spending 50% of the microprocessor cycles servicing an interrupt to support the two PWM signals as in the example of the conventional case, the same microprocessor implementing the method 100 of FIG. 4 may only need to spend an average of approximately 10.2% of its cycles servicing an interrupt to support two PWM signals.

One exemplary approach to implementing the method 100 of FIG. 4 is to utilize a component referred to herein as a “PWM event table”. A first illustrative approach to constructing the PWM event table places at least two restrictions on the placement of events. The restrictions require that edge transitions of the pulse width modulation signals are spaced such that no two events are closer together in time than the time spent processing an adjacent event, e.g., no two events may occur closer together than the interrupt service interval (time spent in the interrupt servicing routine). The restrictions may also require that each event involves only one channel.

According to aspects of the present invention, events may be generated by defining a keep-out zone as a minimum distance from an edge transition. Keep-out zones will be described in greater detail herein. The pulse width modulation signals are sorted in order according to duty cycle and a first one of the pulse width modulation signals is placed onto a timeline. The remainder of the sorted pulse width modulation signals are then placed, one at a time, in order by locating a position on the timeline to place the pulse width modulation signal such that each edge transition for that pulse width modulation signal is outside the keep-out zones of edge transitions associated with previously placed pulse width modulation signals.

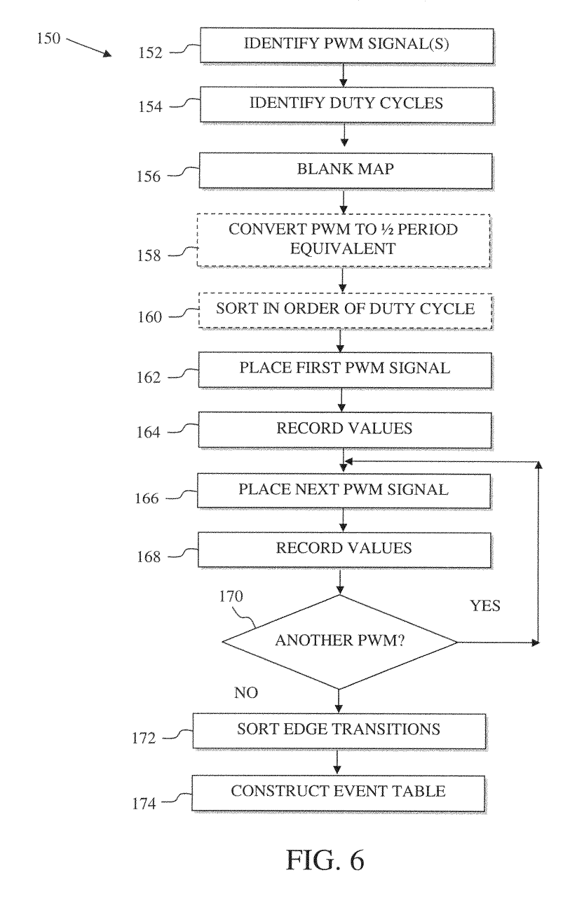

As an example, referring to FIG. 6, considering the above exemplary restrictions, events may be laid out according to the method 150. Each desired PWM signal is identified at 152 and a desired duty cycle identified for each PWM signal at 154. A blank map of one period is created at 156. For each desired PWM channel, the corresponding PWM signal may be converted to their ½ period equivalents at 158. As a few illustrative examples of converting PWM signals to their ½ period equivalents, a “normal” PWM signal that has a duty cycle, designated ‘x’, which is greater than 50% can be represented by a signal with duty cycle (100−x) % and inverted edge directions. Thus, as an example, a positive 70% duty-cycle PWM signal may be designated as being equivalent to a 30% PWM signal for which the first edge is falling and the second edge is rising.

The conversion of PWM signals to their ½ period equivalent may not be necessary. However, such an approach provides a convenient approach to keep all PWM signals within a single period during the process of programmably placing the PWM signals, e.g., where the PWM duty cycles are relatively large. Such an approach may thus make the bookkeeping for zones and regions required by the signal placing algorithm more straight forward.

The various included PWM signals may also be sorted at 160, such as by sorting the PWM signals in order of descending duty cycle. A first PWM signal is placed such that the first edge is at 0 on the map at 162 and values for the placed PWM signal may be recorded at 164, such as to record the location that may subsequently be used to characterize event information as will be described in greater detail below. Moreover, “keep-out zones” may be defined. A “keep-out zone” designates a marker where an edge of a subsequently placed PWM signal should not occur, such as where a desired edge is closer to an already placed edge than the time it takes for the interrupt routine to execute. That is, the keep-out zones define a band of duration z on each side of a placed edge transition, where z is greater than a predetermined duration, e.g., an interrupt service routine interval.

The next PWM signal is placed at 166, such as by assigning the first edge of the signal so as to not interfere with an existing keep-out zone. For example, the next PWM signal may be placed by assigning the first edge of the next PWM signal to a keep-out zone boundary of an already placed edge. Once a location is selected for the first edge, a check is made to determine whether the second edge of the signal lies within a keep-out zone. If either the first or second edges of the next PWM signal fall within a keep-out zone, the PWM signal is relocated within the map and the first and second edges of the PWM signal are again checked to determine whether they fall within a designated keep-out zone. For example, the next PWM signal may be shifted over to the next keep-out zone boundary, or the next PWM signal may otherwise be shifted at up to the resolution of a slice.

This process may continue in the same manner with each zone boundary until a suitable position is found for which the first and second edges lie outside all keep-out zones. Appropriate information for the placed PWM signal may be stored at 168. A check is made at 170 as to whether there are any additional PWM signals that are to be placed onto the map. If additional PWM signals are to be placed on the map, then the flow loops back to 166. Otherwise, a list of edge transitions is created and the list is sorted at 172, e.g., such as by sorting the list of edges in order of ascending time. An event table is constructed at 174 from the edge data. Thus, for example, each event in the table of events is ordered to correspond with the order of time of the sorted list of edges. For each event, a time to next event parameter is stored. The time to next event parameter stores the time difference between the relative time within a period associated with the current event and the relative time within the same period associated with an edge transition event corresponding to the adjacent edge transition in the sorted list of edges. The time to next event may also be corrected or otherwise compensated by subtracting a predetermined amount of time required to process a given event, e.g., the amount of time spent in the interrupt service routine before the event transition occurs.

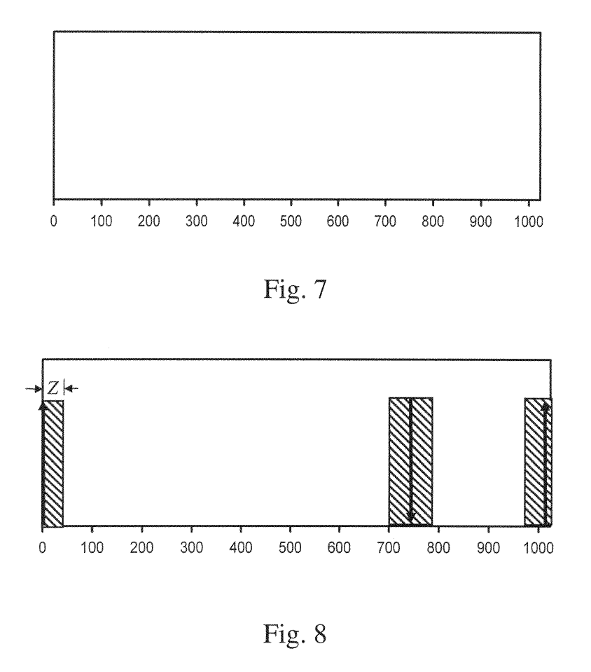

As an illustrative example of implementing the method 150, assume that a map is to be created for two PWM signals, such as the signals illustrated in FIG. 5, having 10-bit resolution. As such, the period P in this example is 1024 cycles. With reference to FIG. 7, an illustrative blank map is shown. The x-axis or axis of abscissa maps a range from 0 to 1023 cycles corresponding to the required slices for 10-bit resolution and is evenly divided by intervals of 100 cycles. The y-axis or axis of ordinate is dimensionless.

As noted above, the method may convert the signals to their half period equivalent. Assume for purposes of illustration that the PWM signal on Channel 1 goes active high at time 0 and remains high for 730 of the 1024 slices. Also assume that the PWM signal on Channel 2 goes high after 330 slices and remains high for 220 slices. The PWM signal on Channel 1 thus has a duty cycle of 730/1024=71.3% and the PWM signal on Channel 2 has a duty cycle of 21.5%. As such, when constructing the event map, it may be useful to conceptualize the PWM signal on Channel 1 as being represented by a signal with duty cycle (100-71.3) % or 28.7% and inverted edge directions.

Depending upon the specific implementation and the nature of the signals, it may be useful to sort or otherwise select the signals, such as by order of duty cycle or some other useful parameter. Sorting or selecting in a sorted order prior to placement may result in an efficient implementation. If the signals are not sorted, a situation may arise where not all of the signals can be placed, e.g., depending upon the specifics of the algorithm utilized for the selection of the placement of signals in view of previously placed signals and their corresponding keep-out zones.

Referring to FIG. 8, the first PWM signal is placed at 0. In this example, it was determined to place the PWM signal on Channel 1 as the first PWM signal. As such, an event recording the rising edge is placed at 0 and an event describing the falling edge is recorded at 730. Continuing to use this illustrative interrupt service routine time of 26 cycles, keep-out zones z having a width of 26 cycles are provided on each side of the edge transitions placed on the map. The keep-out zones placed on the map are shown in cross-hatch. Note that the keep out zone around the first edge wraps around to the end of the adjacent period. For each edge of the pulse, appropriate values for channel and direction may be recorded at 160 as noted above.

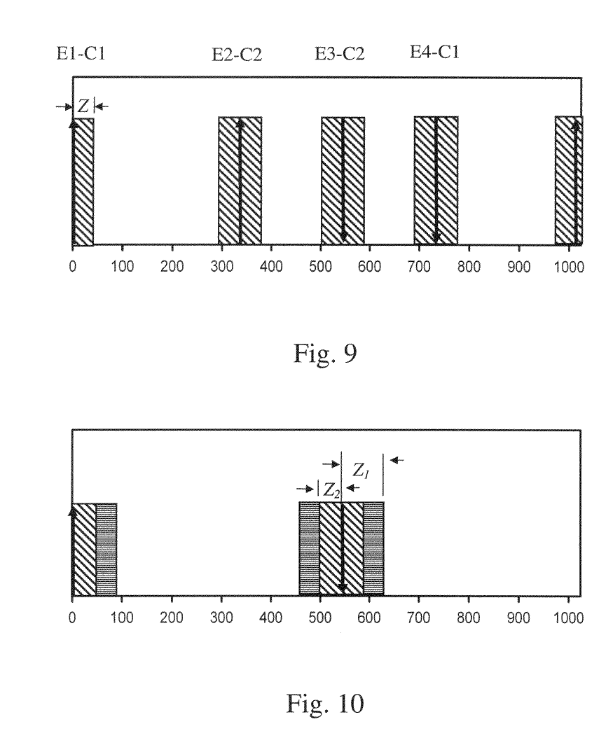

The next signal (channel 2) is then placed on the map, as shown in FIG. 9. In this example, the placement of the edges of channel 2 do not fall within the keep-out zones of the PWM signal on channel 0, so the edges are placed. Depending upon the specific implementation, an algorithmic approach to edge placement may have alternatively sorted in ascending order by duty cycle and thus, placed the channel 2 signal first.

As yet a further example, if the exact edge transition locations as shown in FIG. 5 are not essential, an exemplary algorithmic approach to the method of FIG. 6 would identify channels 1 and 2 and their corresponding duty cycles at 152, 154 and create a blank map at 156 having a period of 1024 in the current example of 10-bit resolution. Since the duty cycle of channel 1 exceeds 50%, it is converted to its ½ period equivalent at 158. The signals may then be sorted or otherwise selected at 160 by duty cycle. Under this arrangement, channel 2 is selected first at 162 and is placed at time 0. Channel 2 thus has a rising edge at 0 and a falling edge at 220 and each edge is bounded on both sides by a keep-out zone of 26. Channel 1 is then placed, such as by positioning the first edge at the edge boundary of the keep-out zone of the first edge of channel 2, e.g., at 26 in the above example. Since channel 1 was inverted due to originally exceeding 50% duty cycle, the falling edge is placed at 26, and the rising edge is placed at 294 (1024−730). Each edge of channel 1 is also bounded by a keep-out zone of 26. In this example, there are no conflicting edge placements so the process of signal placement can terminate, corresponding events can be created and those events may be added to an event table.

If one of the edges (rising or falling) of the PWM signal on Channel 1 were to interfere with a keep-out zone of the PWM signal(s) already placed on the map, then the method may reposition the current PWM signal, e.g., by sliding the signal along the map so that the edges of current PWM signal do not interfere with existing keep-out zones. For example, the current PWM signal may be slid to a nearby edge boundary of an already placed edge, or the current PWM signal may be placed some other suitable location.

For purposes of illustration, an exemplary event table for the signals of FIG. 5 is shown as Table 1 below. The below table assumes that a corresponding interrupt service routine requires 26 cycles. The ‘Adjusted Time’ parameter takes into account the interrupt service routine time to compensate the time to next event parameter.

TABLE 1
Event table for two PWM signals

| | | | Time to Next | |
|---|---|---|---|---|
| Event | Channel | Direction | Event | Adjusted Time |
| 1 | 1 | 1 | 330 | 304 |
| 2 | 2 | 1 | 220 | 194 |
| 3 | 2 | 0 | 180 | 154 |
| 4 | 1 | 0 | 294 | 268 |

Signals with very low or very high duty cycle, for which the two edges of the PWM pulse are separated by less than z (keep-out zone value), would technically be disallowed, since the events would violate the keep-out restriction. A first exemplary approach to address this issue is to limit the duty cycle of all PWM signals to a range over which the two edges of the basic pulse are a minimum of z apart. Such a limitation simplifies the overall algorithm, though it may preclude signal levels close to zero and full range. This restriction, however, may be acceptable for many applications.

As yet another illustrative example, events with duration less than the interrupt service interval can be handled by idling for the required number of cycles, then processing the next event. For example, before exiting the interrupt service routine, a check may be made as to whether the time to next event is less than the interrupt service routine cycle time. If the time to next event is less than the interrupt service routine cycle time, the service routine may idle within the interrupt service routine until the time to process the next event. Referring back to FIG. 4, before configuring the timer for the time to next event at 114, a small delay can be implemented, e.g., the microcontroller 10 may idle for the necessary delay at 114, increment the event pointer at 118, 120, 122 and set the channel(s) according to the new event at 108 such that two or more events spaced in time are processed within a single interrupt service routine instance. Such additional processing to cycle through a next event within the interrupt service routine instead of returning from the interrupt may allow very low (or very high) duty cycle signals, for which the duty cycle is less than the interrupt service time. Such additional processing may also enable a relatively fine resolution of edge placement, e.g., if the timer resolution is coarser than the instruction clock.

There are several concepts that may be implemented to extend the functionality or enhance the performance of the basic PWM algorithm described above. A first concept that may be implemented to extend the functionality of PWM algorithm is referred to herein as “Incremental Application of Changes”. It may take a substantial amount of time to programmatically find the appropriate placement of all PWM signals and to generate an event table, particularly as the number of signals increases. However, the entire event table may not require regeneration each time a signal changes. Rather, it may be satisfactory and actually quicker to programmatically apply updates incrementally. As an example, if the PWM duty cycle of a select PWM signal is changed, the events associated with that PWM signal may be removed from the table and the new edge transitions corresponding to the new duty cycle of the PWM signal may be inserted within the table, provided that a suitable location can be found using the normal criteria for placement described herein. Under this arrangement, it may only be necessary to fully reorganize the signals if no suitable placement is found for the changed signal.

Alternatively, if the signals are expected to vary only slightly during normal operation, a dual-zone approach may minimize the amount of time required to adjust signals. Referring to FIG. 10, signals may be placed initially using the maximum value, e.g., Z₁, for the keep-out zone. This ensures maximum separation between adjacent signal edges, and correspondingly adjacent events, at the outset. For subsequent adjustments however, the width of the keep-out zone may be decreased, e.g., to a minimum value Z₂. The value of Z₂ may be just above the interrupt service time interval as an example. In this way, a signal edge may vary in-place somewhat without encroaching on the narrower keep-out zone of another signal. If a signal changes significantly, such that it does violate a keep-out zone restriction, it may be removed and placed again, as described above, or the signal set may be completely relocated. Moreover, it may be possible to dynamically calculate the optimum keep-out zone width at placement time based upon signal values, such that it provides the maximum range of variation for each of the signals.

Relatively high efficiency of operation, rapid placement of signals and relatively large permissible keep-out zone widths may also be achieved by using alternate placement strategies, such as utilizing coincidental placement of signal edges. Under this approach, an event may correspond to simultaneous (or nearly simultaneous) changes in more than one signal. This approach may be exploited by a corresponding hardware configuration, for which the channels selected for coincident edge placement correspond to separate bits within one port register of the microcontroller. For each event, rather than calculating a signal index and direction for a single signal/channel, the full state of all PWM signals is determined for that slice or point in the cycle. An example is illustrated in Table 2. In this example, it assumes that there are 8 PWM channels, each channel corresponding to a corresponding bit of a port register of the microcontroller. When an interrupt is called to carry out an event, a data parameter corresponding to the new port state can then simply be transferred to the port register. Note that the events in Table 2 generate the same PWM output as the events shown in Table 1 for the exemplary signals of FIG. 5.

TABLE 2
Event table for two PWM signals with coincident edges

| | | Time to Next | |
|---|---|---|---|
| Event | Port State | Event | Adjusted Time |
| 1 | 0000 0001 | 330 | 304 |
| 2 | 0000 0011 | 220 | 194 |
| 3 | 0000 0001 | 180 | 154 |
| 4 | 0000 0000 | 294 | 268 |

If PWM outputs are distributed among multiple ports, the outputs generally cannot be made to change on exactly the same cycle, but rather will have small offsets between them, since each port register must typically be changed in a separate instruction. It is therefore more complicated to determine the appropriate arrangement of signals. However, such offsets due to updating multiple ports can be computed because the microcontroller instruction cycles required to update a port register are determinable. Moreover, the use of the port state version of the event table shown in Table 2 is equally applicable to methods that do not allow coincident edges.

Under certain circumstances, the utilization of an algorithmic approach to signal placement as set out more fully herein can be time-consuming. Moreover, the time required to place all signals varies as a function of signal values, since one or more of the signals may require multiple attempts at placement for certain value combinations. According to aspects of the present invention, an approach to placing signals may be implemented using one or more lookup templates in which signal placement may be predetermined, e.g., as a function of signal value ranges. With this approach, the time required to resolve signal locations may be made relatively small and is consistent in implementation.

The order in which signals can be placed to satisfy a desired timing and edge separation criteria for a particular implementation is likely generally the same over a range of signal values. Moreover, there is likely a manageable number of range combinations with equivalent placement patterns to make this approach practical.

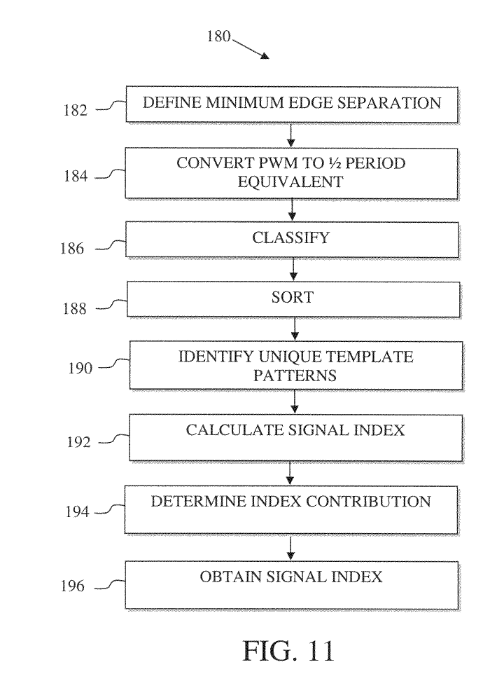

Referring to FIG. 11, a lookup template approach 180 to signal placement is illustrated. A minimum edge placement is selected at 182. For example, assume that in an illustrative template approach, four signals are to be operationally defined which are to be placed with a minimum required separation between edges of one sixteenth the PWM period. Signals with greater than 50% duty cycle may be converted to their half-period equivalents at 184 in a manner analogous to that described more fully herein.

For example, if a period is conceptually divided up into octants, then signals converted to their ½ period equivalent may reside in one of the first four octants of the period. Under this configuration, there may be 256 (4⁴) possible signal combinations to consider. Without first converting signals to their ½ period equivalent, there are 4096 (8⁴) combinations to consider before sorting and reduction. Thus, the conversion provides a simplification and computation reducing mechanism that may be utilized.

Signals are classified at 186, such as by which range they occupy. Keeping with the above example, arbitrarily, an octant is defined as one eighth of the PWM period. Thus, a signal with 17% duty cycle occupies the second octant, and a signal with a duty cycle of 33% occupies the third octant.

If signals with greater than 50% duty cycle were converted to their half-period equivalents, all signals will fall into the first half of the range, e.g. octants 1, 2, 3 and 4 in the present example. As noted above, in the current example, with four signals, the number of possible range combinations is then 4⁴=256. The signals are sorted at 188. Keeping with the above example, sorting the signals, the number of sorted combinations may be some smaller number, e.g., 35. That is, the signal range combinations 1/2/3/4, 4/1/2/3, 3/4/1/2, etc. may be equivalent, since they can all be sorted to a common 1/2/3/4 configuration, as long as the channel associations are tracked through the sort.

Unique template patterns are identified at 190. For certain range combinations, signals may be placed in the same order, and therefore the required number of unique template patterns can be reduced, e.g., to 9 in this example. Let P define a PWM period; BUFFER define a minimum separation between edges; T0-T3 define PWM values for signals 0-3; CO↓-C3↓ define positive-going edges for signals 0-3; and Co≡-C3≡ define negative-going edges for signals 0-3.

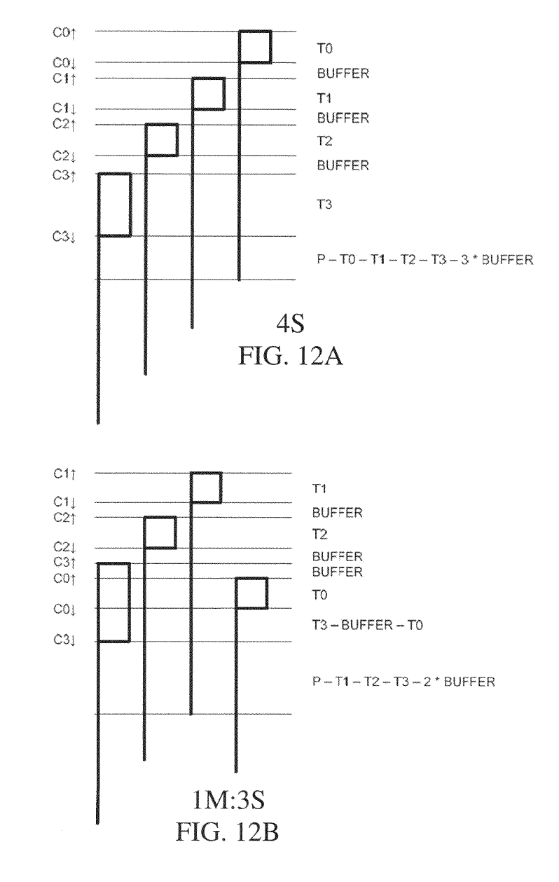

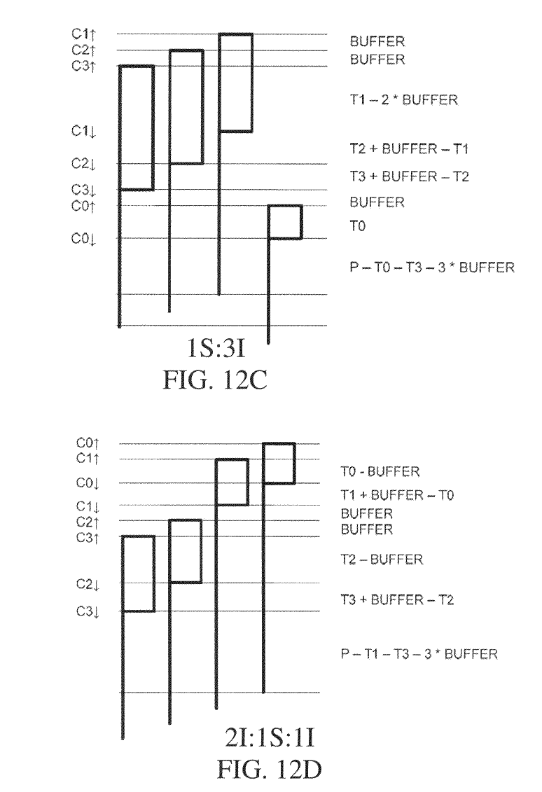

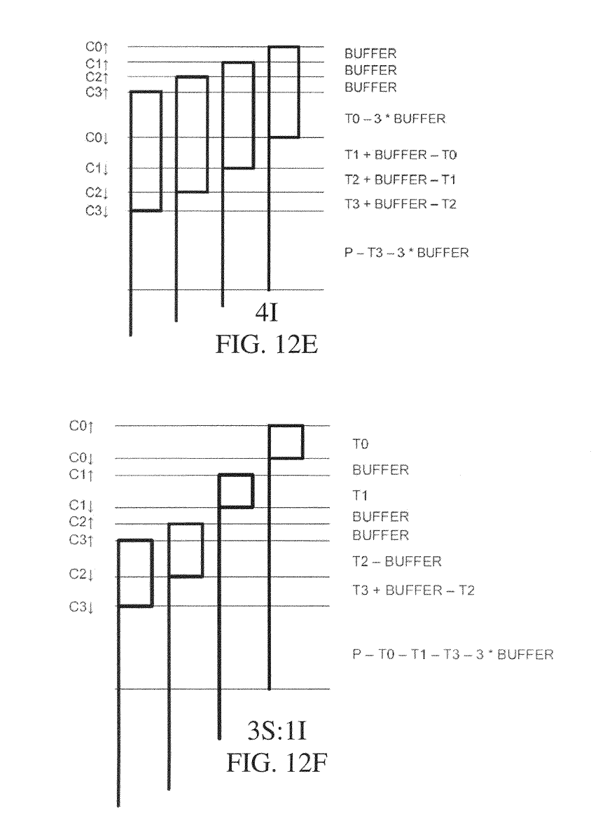

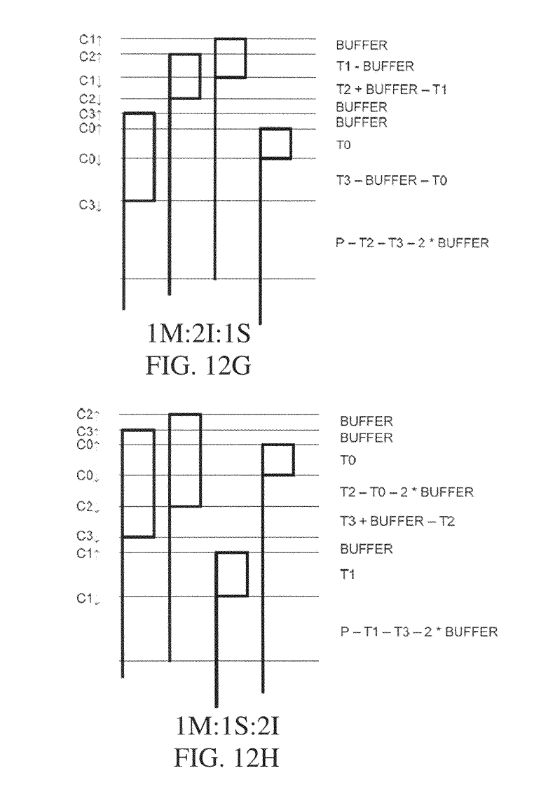

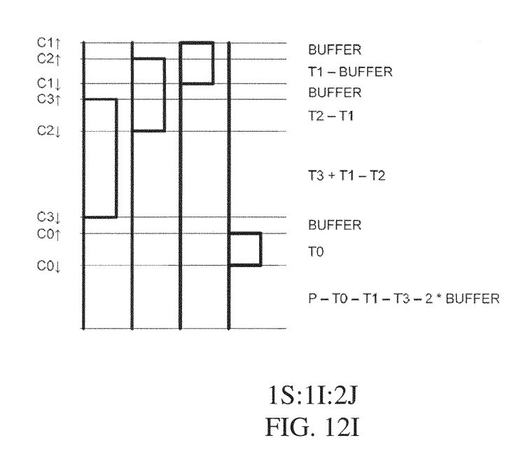

With reference to FIGS. 12A-12I, several exemplary signal configurations are charted out to illustrate exemplary signal placement. The quantities above the vertical lines indicate time intervals between the corresponding edges. Each of the patterns can be identified by a descriptor which indicates the general placement of the signals from smallest to largest. Exemplary placement designators may include I: Intersecting—this signal overlaps partially with another; M: Medial—this signal is situated completely within another; S: Sequential—this signal is disjoint with its neighbors; J: Joint—this signal is one of two sequential signals that overlap a third.

Further, each designator is preceded by a digit that indicates the number of signals that follow that designation. For example, the designator 1M:3S indicates that the smallest signal is medial to another, and the remaining three signals are arranged sequentially. A template lookup table can be constructed to map each of the 35 sorted combinations of signals to one of the 9 placement patterns, as shown in Table 3. In this table, the values in the range columns indicate the number of signals belonging in each of the corresponding octants. Each row corresponds to a particular signal configuration, or case, and the column in which the x appears for each case indicates the pattern that applies to that case. For example, four PWM signals with duty cycle 18%, 30%, 42% and 47% can be categorized as occupying octants 2, 3, 4, and 4, respectively. There is one signal in each of octants 2 and 3, and two signals in octant 4, corresponding to case 23. The corresponding template pattern that should be employed is therefore 1S:3I.

There is one exception within the table. The case for which the 4 signals cover all four available octants (case 25) maps to two patterns (1S:3I, 1S:2I:1J). In this illustrative example, the pattern selection then depends on whether the signal in the second octant is in the lower half of the octant (mapping to 1S:2I:1J) or the upper half (mapping to 1S:3I). This exception is indicated by an ‘s’ in each of the two possible pattern columns.

To facilitate lookup of the proper template entry, a signal index may be calculated at 192, such as by sorting signals in order of increasing value. For each signal i, an index contribution sᵢ is determined at 194, e.g., calculated as sᵢ=4^{k-1}, where k is the number of the octant occupied by the signal (1, 2, 3 or 4) and the index contributions from all signals are summed at 196 to obtain the signal index S=Σᵢ(sᵢ). The signal index calculated in this way is given in the Index column in Table 3. Since each of the 35 possible signal combinations has a unique index value, this index can be used to determine the correct map entry for any given signal set.

Other variations on the formulation described here may be employed within the fundamental scope of the template lookup approach. Variations may include signal segregation ranges, means of determining an index value or values for a signal set, number of template patterns, format of template pattern descriptions, and information contained within a template pattern entry.

TABLE 3
Signal Pattern Map

| | Range (octant) | | | | Pattern | | | | | | | | | |
|---|---|---|---|---|---|---|---|---|---|---|---|---|---|---|
| Case | 1 | 2 | 3 | 4 | 4S | 4I | 3S:1I | 1S:3I | 1S:2I:1J | 1M:3S | 2I:1S:1I | 1M:2I:1S | 1M:1S:2I | Index |
| 1 | 4 | | | | x | | | | | | | | | 4 |
| 2 | 3 | | 1 | | x | | | | | | | | | 19 |
| 3 | 3 | 1 | | | x | | | | | | | | | 7 |
| 4 | 2 | 2 | | | x | | | | | | | | | 10 |
| 5 | | | 4 | | | x | | | | | | | | 64 |
| 6 | | | 3 | 1 | | x | | | | | | | | 112 |
| 7 | | | 2 | 2 | | x | | | | | | | | 160 |
| 8 | | | 1 | 3 | | x | | | | | | | | 208 |
| 9 | | | | 4 | | x | | | | | | | | 256 |
| 10 | 2 | | | 2 | | | x | | | | | | | 130 |
| 11 | 2 | | 2 | | | | x | | | | | | | 34 |
| 12 | 2 | | 1 | 1 | | | x | | | | | | | 82 |
| 13 | 2 | 1 | | 1 | | | x | | | | | | | 70 |
| 14 | 2 | 1 | 1 | | | | x | | | | | | | 22 |
| 15 | 1 | 3 | | | | | x | | | | | | | 13 |
| 16 | 1 | 1 | 2 | | | | x | | | | | | | 37 |
| 17 | 1 | | | 3 | | | | x | | | | | | 193 |
| 18 | 1 | | 3 | | | | | x | | | | | | 49 |
| 19 | 1 | | 1 | 2 | | | | x | | | | | | 145 |
| 20 | 1 | | 2 | 1 | | | | x | | | | | | 97 |
| 21 | | 1 | | 3 | | | | x | | | | | | 196 |
| 22 | | 1 | 3 | | | | | x | | | | | | 52 |
| 23 | | 1 | 1 | 2 | | | | x | | | | | | 148 |
| 24 | | 1 | 2 | 1 | | | | x | | | | | | 100 |
| 25 | 1 | 1 | 1 | 1 | | | | s | s | | | | | 85 |
| 26 | 3 | | | 1 | | | | | | x | | | | 67 |
| 27 | | 2 | 1 | 1 | | | | | | | x | | | 88 |
| 28 | | 4 | | | | | | | | | x | | | 16 |
| 29 | | 3 | | 1 | | | | | | | x | | | 76 |
| 30 | | 3 | 1 | | | | | | | | x | | | 28 |
| 31 | | 2 | | 2 | | | | | | | x | | | 136 |
| 32 | | 2 | 2 | | | | | | | | x | | | 40 |
| 33 | 1 | 2 | | 1 | | | | | | | | x | | 73 |
| 34 | 1 | 2 | 1 | | | | | | | | | x | | 25 |
| 35 | 1 | 1 | | 2 | | | | | | | | | x | 133 |

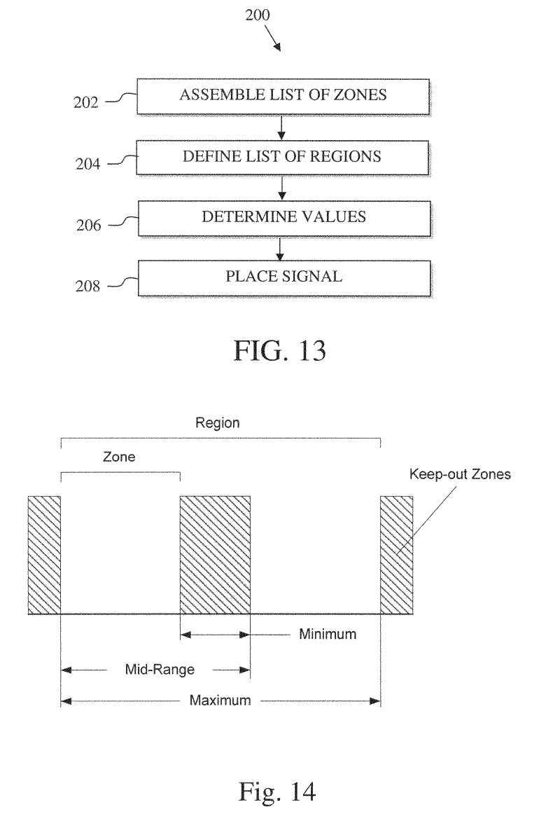

A pseudo-code implementation shown below illustrates yet another exemplary approach for table construction. To place each signal, the program performs the method/algorithm 200 shown in FIG. 13. The algorithm 200 assembles a list of open zones at 202. For example, the list of open zones may be defined as contiguous free space between any two keep-out zones. A list of regions is defined at 204 consisting of every single open zone or pair of open zones. For each region, values are determined at 206, such as a minimum, maximum and mid-range value corresponding to the minimum and maximum signal widths that would fit within the region, and the distance between the left sides of the zones comprising the region, respectively. Referring to FIG. 14, a map illustrates these values. Note that if the region consists of a single open zone, the minimum and mid-range values are both zero.

The signal is then placed at 208 within the first region for which the signal width is between the minimum and maximum values for the region. If the signal width is greater than the mid-range value, the first edge of the signal is aligned with the left edge of the first zone in the region. Otherwise, the second edge of the signal is aligned with the left edge of the second zone in the region.

```
// Pseudo-code Implementation of event table construction
initialize edge event table
for each (signal in the set of signals)
{
    if (signal.value > 50%)
    {
        // convert signal to half-period equivalent
        signal.value = 100% − signal.value
        signal.direction = opposite(signal.direction)
    }
}
sort signals by signal.value, ascending
for each (signal in the set of signals),
    while (signal placement is successful)
{
    // zones = find_zones (signal, edges, PERIOD, BUFFER)
    initialize set of zones
    sort edges by time, ascending
    if (edge event table is empty)
    {
        add new zone to set of zones
        zone.left = 0
        zone.right = PERIOD − BUFFER
    }
    else
    {
        for each (edge in the table of edge events)
        {
            if (([next edge].time − [this edge].time) > 2 *
            BUFFER_SIZE)
            {
                add new zone to set of zones
                zone.left = [this edge].time + BUFFER
                zone.right = [next edge].time − BUFFER
            }
        }
        add new zone to set of zones
        zone.left = [this edge].time + BUFFER
        zone.right = PERIOD − BUFFER
    }
    // regions = find_regions (zones)
    initialize set of regions
    for each ([zone A] in the set of zones)
    {
        // form region from zone A
        add new region to set of regions
        region.left = [zone A].left
        region.right = [zone A].right
        region.minimum = 0
        region.maximum = [zone A].right − [zone A].left
        region.mid-range = 0
        for each ([zone B] beyond [zone A])
        {
            // form region from zone A and zone B
            add new region to set of regions
            region.left = [zone A].left
            region.right = [zone B].right
            region.middle = [zone B].left
            region.minimum = [zone B].left − [zone A].right
            region.maximum = [zone B].right − [zone A].left
            region.mid-range = [zone B].left − [zone A].left
        }
    }
    for each (region in the set of regions),
        until (signal placement successful)
    {
        if (signal.value between region.minimum and region.maximum)
        {
            add two edges (A, B) to edge event table
            [edge A].channel = signal.channel
            [edge A].direction = signal.direction
            [edge B].channel = signal.channel
            [edge B].direction = opposite(signal.direction)
            if (signal.value > region.mid-range)
            {
                [edge A].time = region.left
                [edge B].time = (region.right + signal.value)
            }
            else
            {
                [edge B].time = region.middle
                [edge A].time = (region.middle − signal.value)
            }
            signal placement is successful
        }
    }
}
if (signal placement not successful)
{
    declare error
}
```

Many variations on the fundamental algorithm described above are possible without deviating appreciably from the scope of the proposed invention. For example, the timer described herein may be implemented as either hardware or software.

According to aspects of the present invention, the capabilities of a microcontroller are augmented for generating multiple analog signals, e.g., such that either existing microcontrollers may be used in applications for which no device could otherwise fulfill the requirements, or lower cost devices may be employed in applications that would otherwise require more expensive alternatives.

As will be appreciated by one of skill in the art, the various aspects of the present invention may be embodied as a method, system, or computer program product. Moreover, the various aspects of the present invention may take the form of an entirely hardware embodiment or an embodiment combining software and hardware aspects.

The present invention is described herein with reference to schematics, flowchart illustrations and/or block diagrams of methods and apparatus systems according to embodiments of the invention. It will be understood that each block of the flowchart illustrations and/or block diagrams, and combinations of blocks in the flowchart illustrations and/or block diagrams may also be implemented by computer program instructions. These computer program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks.

The equations in the specification and the flowcharts and block diagrams in the Figures illustrate the architecture, functionality, and operation of possible implementations of systems, methods and computer program products according to various embodiments of the present invention. In this regard, each equation or block in the flowchart or block diagrams may represent a module, segment, or portion of code, which comprises one or more executable instructions for implementing the specified logical function(s). It should also be noted that, in some alternative implementations, the functions might occur out of the order as presented herein. For example, two blocks shown in succession may, in fact, be executed substantially concurrently, or the blocks may sometimes be executed in the reverse order, depending upon the functionality involved. It will also be noted that each equation in the specification, and each block of the block diagrams and/or flowchart illustration, and combinations of blocks in the block diagrams and/or flowchart illustration, can be implemented by special purpose hardware-based systems that perform the specified functions or acts, or combinations of special purpose hardware and computer instructions.

The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Having thus described the invention of the present application in detail and by reference to preferred embodiments thereof, it will be apparent that modifications and variations are possible without departing from the scope of the invention defined in the appended claims.

What is claimed is:

1. A method of generating one or more pulse width modulation signals comprising:
identifying an event table associated with at least one desired pulse width modulation signal, the event table having a plurality of events where each event includes a time to next event parameter, wherein each desired pulse width modulation signal is characterized by a first event in the event table that designates a transition from a first state to a second state and a second event in the event table that designates a transition from the second state back to the first state;
associating a corresponding output for each desired pulse width modulation signal;
setting an event pointer to point to a predetermined event in the event table, corresponding to a current event;
repeatedly cycling through each event in the event table by:
updating the output for at least each pulse width modulation signal associated with the current event having a designated state transition;
detecting that a time period has lapsed corresponding to the time to next event parameter associated with the current event; and
incrementing the event pointer to point to a next event in the event table, wherein the event pointer is reset to the first event if the current event is the last event in the event table; and
conveying each pulse width modulation signal to a corresponding circuit.

2. The method according to claim 1, further comprising constructing the event table by:
identifying each desired pulse width modulation signal;
identifying a desired duty cycle for each desired pulse width modulation signal;
sorting the desired pulse width modulation signals in an order corresponding to their duty cycle over a given period;
creating an event for each instance within the period where there is at least one edge transition corresponding to a designated state change from high to low or low to high;
identifying the time within the given period until the next edge transition; and
associating the identified time with the time to next event parameter associated with the event.

3. The method according to claim 2, wherein constructing the event table further comprises creating a unique event for each edge transition within the given period such that there are two events associated with each desired pulse width modulation signal.

4. The method according to claim 3, further comprising:
defining parameters for each event including at least a channel parameter that specifies a select pulse width modulation signal for processing and an edge direction parameter designating whether the select pulse width modulation channels should change from a low state to a high state, or from a high state to a low state;
wherein updating the output for at least each pulse width modulation signal associated with the current event having a designated state transition further comprises:
identifying the select pulse width modulation signal based upon the channel parameter associated with the current event and setting the state of the select pulse width modulation signal according to the direction parameter of the current event.

5. The method according to claim 2, wherein constructing the event table further comprises creating a single event for each time within the given period that there is at least one edge transition, further comprising defining a data parameter that characterizes the state of every desired pulse width modulation signal at that time.

6. The method according to claim 2, wherein constructing an event table further comprises:
arranging the pulse width modulation signals such that each event corresponds to a state transition for a single pulse width modulation signal; and
spacing the edge transitions of the pulse width modulation signals such that no two events are spaced closer together in time than the time spent processing an adjacent event.

7. The method according to claim 2, wherein the time to next event parameter for a select event comprises:
computing a time value as the time difference between the relative time within the period associated with the select event and the relative time within the period associated with a next event in the event table, further subtracting from the time value, a predetermined amount of time required to process the select event.

8. The method according to claim 1, further comprising constructing the event table by:
identifying each desired pulse width modulation signal;
identifying a desired duty cycle for each desired pulse width modulation signal;
defining a keep-out zone as a minimum duration from an edge transition corresponding to a state change from low to high or high to low;
sorting the desired pulse width modulation signals in an order corresponding to their duty cycle;
placing a first one of the pulse width modulation signals onto a timeline;
placing the remainder of the sorted pulse width modulation signals in order by:
locating a position on the timeline to place the next pulse width modulation signal such that each edge transition for that pulse width modulation signal is outside the keep-out zones of edge transitions associated with previously placed pulse width modulation signals;
creating an event for each instance within the period where there is at least one edge transition; and
identifying the time within the given period until the next edge transition and associating the identified time with the time to next event parameter associated with the event.

9. The method according to claim 8, further comprising converting each pulse width modulation signal having a duty cycle of greater than 50 percent to a half period equivalent by inverting the edge directions of the pulse width modulation signal and by subtracting the duty cycle from 100% before sorting the pulse width modulation signals.

10. The method according to claim 8, wherein defining a keep-out zone further comprises:
assigning a first keep-out zone having a first duration to events added to the event table where each keep-out zone defines a minimum duration between adjacent events in the event table; and
assigning a second keep-out zone having a second duration that is less than the first duration for subsequent revisions to events in the event table.

11. The method according to claim 10, further comprising dynamically computing an optimum keep-out zone width at placement time based upon pulse width modulation signal values.

12. The method according to claim 1, further comprising programmatically revising the event table to accommodate changes to a select pulse width modulation signal by removing from the event table, only those events corresponding to the select pulse width modulation signal and by creating new events for the event table corresponding to the changes made to the select pulse width modulation signal.

13. The method according to claim 1, wherein edge transitions are placed using lookup templates in which signal placement is predetermined as a function of signal value range.

14. The method according to claim 13, wherein edge transitions are placed using lookup templates comprises:
classifying the pulse width modulation signals;
sorting the classified pulse width modulation signals;
identifying unique template patterns; and
placing the pulse width modulation signals according a selected one of the template patterns.

15. The method according to claim 14, further comprising:
calculating a signal index;
sorting the pulse width modulation signals;
determining an index contribution; and
determining a select one of the lookup templates for a given signal set of the desired pulse width modulation signals by indexing a table of templates based upon the computed signal index value.

16. A pulse width modulation system comprising:
a microcontroller having a processor, a timer programmable by the processor, at least one output pin and memory accessible by the processor;
program code resident in the memory that is executable by the processor to run a pulse width modulation generation algorithm comprising:
identifying an event table associated with at least one desired pulse width modulation signal, the event table having a plurality of events where each event includes a time to next event parameter, wherein each desired pulse width modulation signal is characterized by a first event in the event table that designates a transition from a first state to a second state and a second event in the event table that designates a transition from the second state back to the first state;
setting an event pointer to point to a predetermined event in the event table, corresponding to a current event;
repeatedly cycling through each event in the event table by:
updating the output for at least each pulse width modulation signal associated with the current event having a designated state transition;
detecting that a time period has lapsed corresponding to the time to next event parameter associated with the current event;
incrementing the event pointer to point to a next event in the event table, wherein the event pointer is reset to the first event if the current event is the last event in the event table; and
conveying each pulse width modulation signal to a corresponding output pin; and
a circuit coupled to output pin.

17. The pulse width modulation system according to claim 16, wherein the output pins of the microcontroller are coupled to a port within the microcontroller and the program code updates each output pin connected to the port by writing a multi-bit value that describes the state of each output pin to a corresponding port register.

18. The pulse width modulation system according to claim 16, wherein the program code performs at least one of editing or creating the event table by defining edge transitions that are placed using preprogrammed lookup templates such that signal placement is predetermined as a function of signal value range.

19. The pulse width modulation system according to claim 16, wherein the program code performs at least one of editing or creating the event table by:
creating a list of edge transitions associated with the pulse width modulation signals; and
sorting the list of edges in order of time;
wherein constructing the event table comprising ordering each event in the event table to correspond with the order of time of the sorted list of edges.

20. The pulse width modulation system according to claim 16, wherein the program code executes in an interrupt service routine that is executed each time the timer counts a duration corresponding to a programmed value.
